(19) United States
(12) Patent Application Publication
(10) Pub. No.: US 2018/0061875 A1
(43) Pub. Date: Mar. 1, 2018

(54) VERTICAL TRANSFER GATE TRANSISTOR AND ACTIVE CMOS IMAGE SENSOR PIXEL INCLUDING A VERTICAL TRANSFER GATE TRANSISTOR

(71) Applicant: STMicroelectronics (Crolles 2) SAS, Crolles (FR)

(72) Inventor: Francois Roy, Seyssins (FR)

(73) Assignee: STMicroelectronics (Crolles 2) SAS, Crolles (FR)

(21) Appl. No.: 15/251,745

(22) Filed: Aug. 30, 2016

(51) Int. Cl. H01L 27/146; H04N 5/225

(52) U.S. Cl. CPC H01L 27/14614; H04N 5/2253; H01L 27/14689

(57) ABSTRACT

A transfer gate transistor includes a semiconductor substrate including a charge collection source region, a portion forming a channel region and a top region forming a drain region. A trench in the substrate surrounds the top region and the portion of the substrate. A vertical insulated gate structure for the transistor is formed in the trench. The vertical insulated gate structure includes an insulating liner on sidewalls and a bottom of said trench and an electrode including an upper conductive part and a lower conductive part. A width of the upper conductive part parallel to an upper surface of the substrate increases as depth from the upper surface of the substrate increases. A thickness of the insulating liner adjacent the upper conductive part decreases as depth from the upper surface of the substrate increases. A thickness of the insulating liner adjacent the lower conductive part is substantially constant.

### TECHNICAL FIELD

The present invention relates to a vertical transfer gate transistor and, in particular, to a vertical transfer gate transistor having a decoupling structure. The present invention further relates to an active CMOS image sensor pixel implementing such a vertical transfer gate transistor.

### BACKGROUND

Reference is made to FIG. 1 showing a cross-section view of an embodiment of a cell 10 of an image sensor as taught by U.S. Pat. No. 8,513,761 (incorporated by reference). This cell 10 is manufactured from a portion of a semiconductor layer (or body) 12 that is lightly-doped with a first conductivity type dopant. The semiconductor material for layer 12 may, for example, comprise silicon. The dopant concentration within layer 12 may, for example, be on the order of from 10¹⁴ to 10¹⁶ atoms/cm³. The layer 12 has a thickness smaller than 10 μm, preferably on the order of from 3 to 5 μm and may, for example, have been formed as the upper silicon layer of a structure of silicon on insulator type (SOI). A wall 14 surrounds the cell 10 and separates the cell 10 from neighboring cells in the image sensor (with a pitch, for example, for adjacent cells of 2 μm). The wall 14 comprises a capacitive deep trench isolation (CDTI) type structure that is formed by a trench 16 having an insulating liner 18 (such as formed by a thermal oxide) and filled with a conductive or semiconductive material (such as a polysilicon material) 20. The trench 16 extends completely through the thickness of the layer 12. The material 20 is electrically connected to be biased with a voltage Vwall. A width of the wall 14 may, for example, be 0.2-0.4 μm.

At a front side of the layer 12, a ring shaped well 22 heavily-doped with a second conductivity type dopant extends into the layer 12. The dopant concentration within well 22 may, for example, be on the order of from 1×10¹⁶ to 1×10¹⁸ atoms/cm³. A lateral width of ring well may, for example, be 0.5-0.6 μm. The ring shaped well 22 surrounds a central first conductivity type region of the layer 12 at the front side. The central first conductivity type region includes a portion 24 of the lightly-doped layer 12 and a top region 26 heavily-doped with the first conductivity type dopant and extending into the layer 12 on top of and in contact with the portion 24. The dopant concentration within top region 26 may, for example, be on the order of from 1×10¹⁹ to 5×10²⁰ atoms/cm³. A lateral width of the central first conductivity type region may, for example, be 0.2-0.6 μm.

The central first conductivity type region is separated from the ring shaped well 22 by a wall 30. A width of the wall 30 may, for example, be 0.2-0.4 μm. The wall 30 comprises a vertical gate (VEGA) electrode type structure that is formed by a trench 32 having an insulating liner 34 (such as formed by a thermal oxide) and filled with a semiconductive material (such as a polysilicon material) 36. The trench 32 extends to a depth that exceeds the thickness of the ring shaped well 22. The material 36 is electrically connected to be biased with a voltage Vgate.

The portion 24, top region 26 and VEGA electrode form a transfer gate transistor (TG) for the cell 10. The ring shaped well 22 supports the formation of a number of other transistors of the planar MOSFET type for the cell 10. These transistors include a reset (precharge) transistor (RST) and a source-follower transistor (SF). The connection and operation of the transistors TG, RST and SF are well known to those skilled in the art with respect to the operation of the cell 10. A read transistor for the cell 10 is not shown in FIG. 1 but is connected to the circuitry in a manner known to those skilled in the art to support signal read out operations. In general, various metallization levels are formed on the front side to ensure the electrical connections to and between the drains, sources, and gates of the various transistors. In particular, an interconnect corresponding to a read node S of the cell is provided between top region 26, the drain of reset transistor RST, and the gate of the source-follower transistor SF is supported by the various metallization levels. The precharge and read transistors may be common to several neighboring cells (for example, shared by a group of four cells).

The cell 10 is a backside illumination (BSI) device. At a back side of the layer 12, a thin layer 40 heavily-doped of the second conductivity type is formed extending into the layer 12 from the rear surface. The dopant concentration within layer 40 may, for example, be on the order of from 1×10¹⁷ to 1×10¹⁹ atoms/cm³. The layer 40 has a function of inversion of the type of majority carriers contained in layer 12. This inversion of the concentration of the type of carriers might also be performed by a MOS capacitance at the rear surface provided with an electrode (metallic, semiconductor, or dielectric), transparent in the useful sensor sensitivity spectrum, which creates a free carrier inversion channel (MOS effect).

The lower surface of each cell is covered with an antireflection coating layer 42 and a filter layer 44 having the desired color for the considered cell, for example, red, green, or blue. Although this is optional in this type of structure, a lens 48 may cover filter layer 44.

Operation of the cell for light detection is well known in the art. There is a phase of photoconversion or integration during which the rear surface is illuminated and electrons are stored in a charge collection area of layer 12. A transfer phase then occurs during which the electrons are transferred from a charge collection area of layer 12 to the top region 26 working as the read node S. During the integration phase, the conduction between the charge collection area of layer 12 and top region 26 is interrupted by the transfer gate transistor (TG) in response to application of the gate voltage Vgate to the conductor 36 of the vertical gate electrode. When the vertical gate electrode is biased at a negative voltage, for example, −1 volt, the portion 24 of the lightly-doped layer 12 is fully depleted from electrons and the passing of the charge carriers is inhibited by the potential barrier (inversion layer) thus created between portion 24 and the charge collection area of layer 12. Thus, the portion 24 plays the role of a controlled channel region and top region 26 corresponds to a drain region of the transfer gate transistor connected to the read node S.

The inventor has noted, however, technical problems with the cell 10 of FIG. 1. One problem concerns a coupling issue from the vertical gate to the sensing node top region 26. This results in sensing node fixed pattern noise (FPN). Another problem concerns a breakdown issue between the sensing node and photosite. Silicon breakdown can occur due to high lateral electric fields between the CDTI and the sensing node and/or between the VEGA and the second node.

There is accordingly a need in the art to address the foregoing problems relating to the cell 10. In particular, there is a need in the art to reduce the electric field while maintaining a satisfactory inversion layer so as to effectively close the channel region.

### SUMMARY

In an embodiment, an integrated circuit comprises: a semiconductor substrate doped with a first conductivity type; a well in said semiconductor substrate, said well doped with the first conductivity type but having a higher doping concentration than the semiconductor substrate; wherein the semiconductor substrate includes a trench surrounding said well and a portion of said semiconductor substrate; and a vertical insulated gate structure in said trench, said vertical insulated gate structure comprising: an insulating liner on sidewalls and a bottom of said trench; and an electrode including an upper conductive part and a lower conductive part, wherein a width of the upper conductive part parallel to an upper surface of the semiconductor substrate increases as depth from the upper surface of the semiconductor substrate increases.

In an embodiment, a method comprises the steps of: forming a trench in a semiconductor substrate; lining sidewalls and a bottom of the trench with an insulating layer; filling the trench with a polysilicon material; and thermally oxidizing an upper portion of the polysilicon material in the trench to shape the upper portion of the polysilicon material such that a width of the upper portion of the polysilicon material parallel to an upper surface of the semiconductor substrate increases as depth from the upper surface of the semiconductor substrate increases.

### BRIEF DESCRIPTION OF THE DRAWINGS

For a better understanding of the embodiments, reference will now be made by way of example only to the accompanying figures in which:

FIG. 1 is a cross-sectional diagram of a pixel cell in accordance with the prior art;

FIG. 2 is a cross-sectional diagram of a vertical transfer gate transistor;

FIG. 3 is a cross-sectional diagram of the insulated vertical gate electrode structure;

FIG. 4 is a cross-sectional diagram of a pixel cell including the vertical transfer gate transistor of FIGS. 2-3; and

FIGS. 5A-5K show process steps for forming the insulated vertical gate electrode structure of FIG. 3.

### DETAILED DESCRIPTION OF THE DRAWINGS

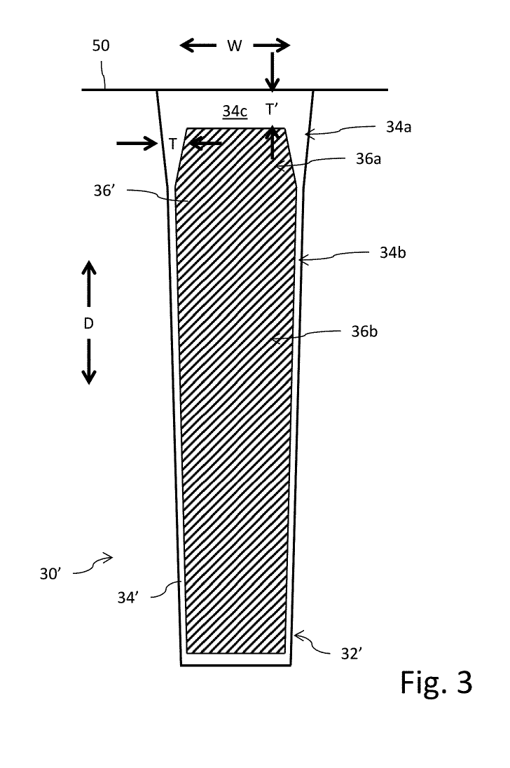

Reference is now made to FIG. 2 showing a cross-sectional diagram of a vertical transfer gate transistor TG′. The transistor TG′ is formed in a portion of a semiconductor layer (or body) 12′ that is lightly-doped with a first conductivity type dopant. The semiconductor material for layer 12′ may, for example, comprise silicon. The dopant concentration within layer 12′ may, for example, be on the order of from 1×10¹⁴ to 1×10¹⁶ atoms/cm³.

At a front side of the layer 12′, a ring shaped well 22′ heavily-doped with a second conductivity type dopant extends into the layer 12′. The dopant concentration within well 22′ may, for example, be on the order of from 1×10¹⁶ to 1×10¹⁸ atoms/cm³. The ring shaped well 22′ surrounds a central first conductivity type region of the layer 12′ at the front side. The central first conductivity type region includes a portion 24′ of the lightly-doped layer 12′ and a top region 26′ heavily-doped with the first conductivity type dopant and extending into the layer 12′ on top of and in contact with the portion 24′. The dopant concentration within top region 26′ may, for example, be on the order of from 1×10¹⁹ to 5×10²⁰ atoms/cm³. A lateral width of the central first conductivity type region may, for example, be 0.2-0.6 μm.

The central first conductivity type region is separated from the ring shaped well 22′ by a wall 30′. A width of the wall 30′ may, for example, be 0.2-0.4 μm. The wall 30′ comprises a vertical gate (VEGA) electrode type structure that is formed by a trench 32′ having an insulating liner 34′ (such as formed by a thermal oxide) and filled with a semiconductive material (such as a polysilicon material) 36′. The trench 32′ extends to a depth that exceeds the thickness of the ring shaped well 22′. The material 36′ is electrically connected to be biased with a voltage Vgate.

The portion 24′, top region 26′ and VEGA electrode material 36′ form, respectively, the channel, drain and gate of the transfer gate transistor TG′. The source of the transfer gate transistor TG′ is formed by a charge collection area of the layer 12′.

Reference is now made to FIG. 3 showing a cross-sectional diagram of the insulated vertical gate electrode structure. The gate electrode includes an upper conductive part 36a and a lower conductive part 36b. The insulating liner 34′ includes upper insulating part 34a surrounding the upper conductive part 36a and a lower insulating part 34b surrounding the lower conductive part 36b.

In cross-section taken perpendicular to an upper surface 50 of layer 12′, the upper conductive part 36a has a trapezoidal shape having a width W parallel to the upper surface 50 of layer 12′ that increases as depth D from the upper surface 50 of layer 12′ increases. It will be understood that the upper conductive part 36a need not be configured as true trapezoid in shape (i.e., it need not have a flat upper surface and need not have a constant slope on the side surface). What is important is that the shape of the upper conductive part 36a provide a surface contour supporting an increasing width W with increasing depth D as noted above. More generically, the upper conductive part 36a has a dome-like outer surface. Furthermore, the lower conductive part 36b has a trapezoidal shape having a width W parallel to an upper surface 50 of layer 12′ that decreases as depth D from the upper surface 50 of layer 12′ increases.

In cross-section taken perpendicular to the upper surface 50 of layer 12′, the upper insulating part 34a adjacent to the upper conductive part 36a has a thickness T parallel to an upper surface 50 of layer 12′ (between the side wall of the trench and the gate electrode 36′) that decreases as depth D from the upper surface 50 of layer 12′ increases. A maximum thickness T of the upper insulating part 34a may, for example, be 40-60 nm in order to ensure sufficient electrical field reduction at the top of the insulated vertical gate electrode structure. Furthermore, the lower insulating part 34b adjacent the lower conductive part 36b has a thickness T parallel to an upper surface 50 of layer 12′ (between the side wall of the trench and the gate electrode 36′) that remains substantially constant (i.e., +/−1 to 3%) as depth D from the upper surface 50 of layer 12′ increases. The substantially constant thickness T of the lower insulating part 34b may, for example, be 10-14 nm in order to ensure efficient control over the inversion layer for vertical transfer gate operation.

The upper insulating part 34a further includes a cap region 34c which covers the upper conductive part 36a. This cap region 34c may, for example, have a thickness T′ perpendicular to the upper surface 50 of layer 12′ of 90-110 nm (between the upper surface and the gate electrode 36′) in order to provide for electrical isolation of the vertical gate electrode. In an alternative embodiment, the cap region 34c may be omitted and the upper surface 50 of layer 12′ would then substantially correspond to the upper surface of the upper conductive part 36a.

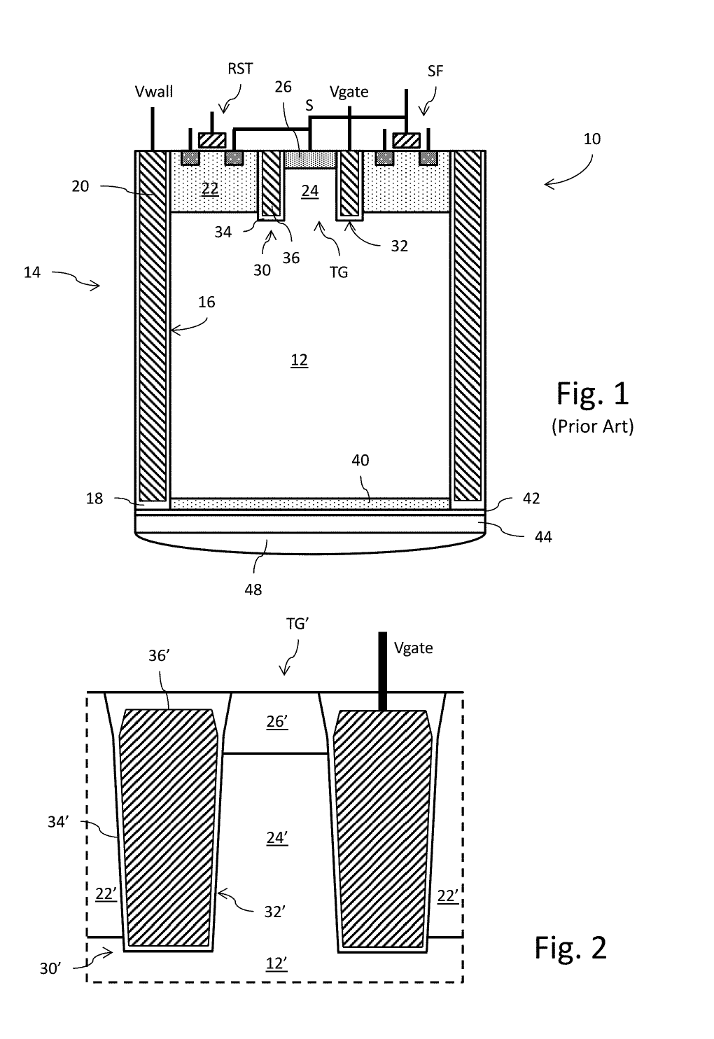

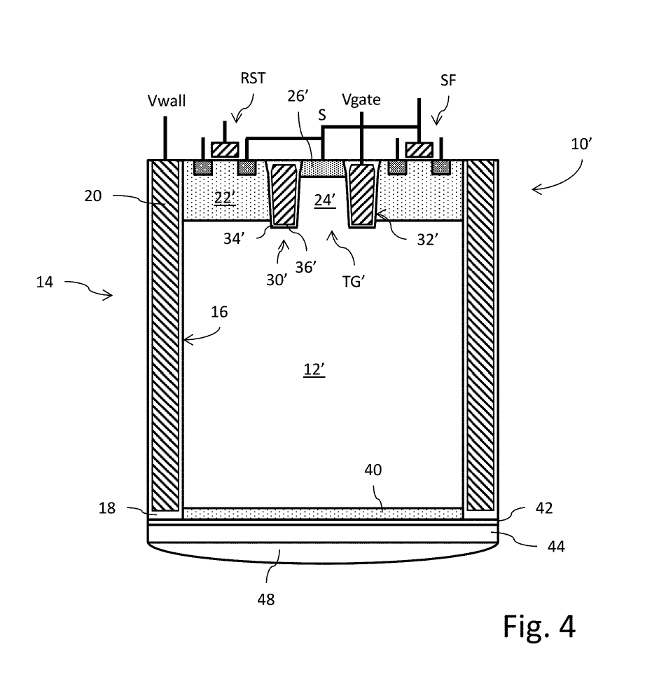

The vertical transfer gate transistor TG′ as shown in FIGS. 2 and 3 is suitable for use in a pixel cell 10′ as shown in FIG. 4. Like reference numbers in FIGS. 1 and 4 refer to like or similar parts.

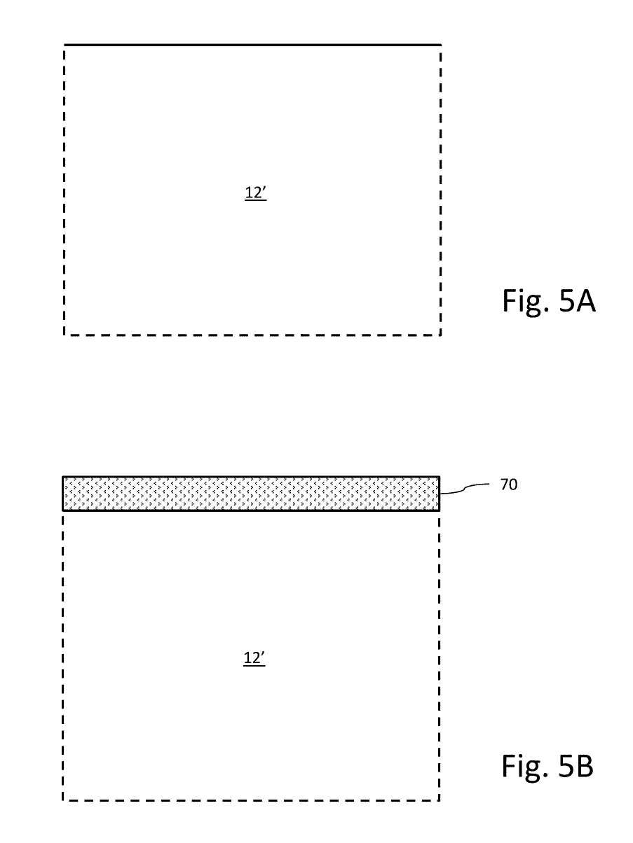

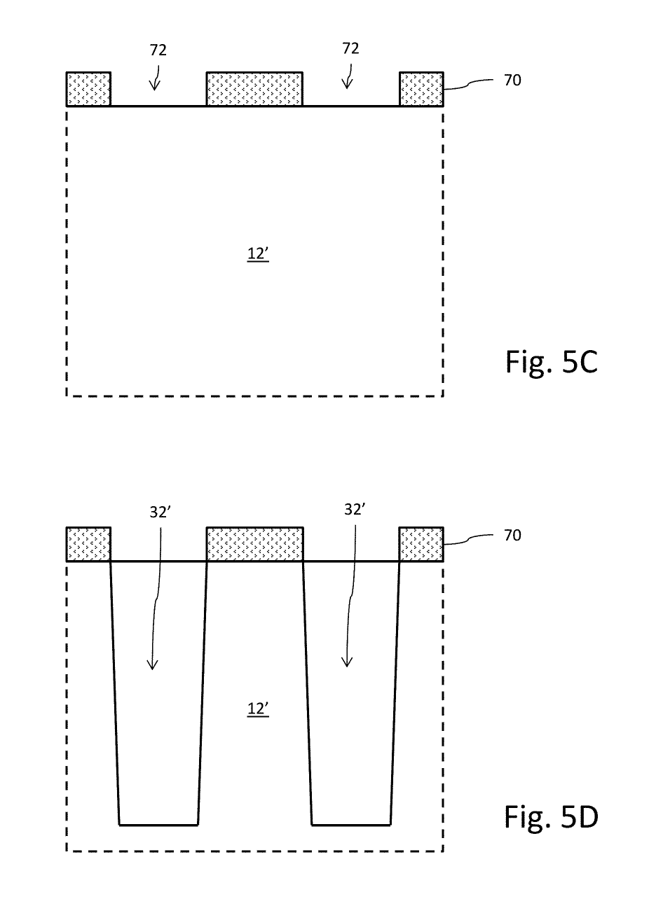

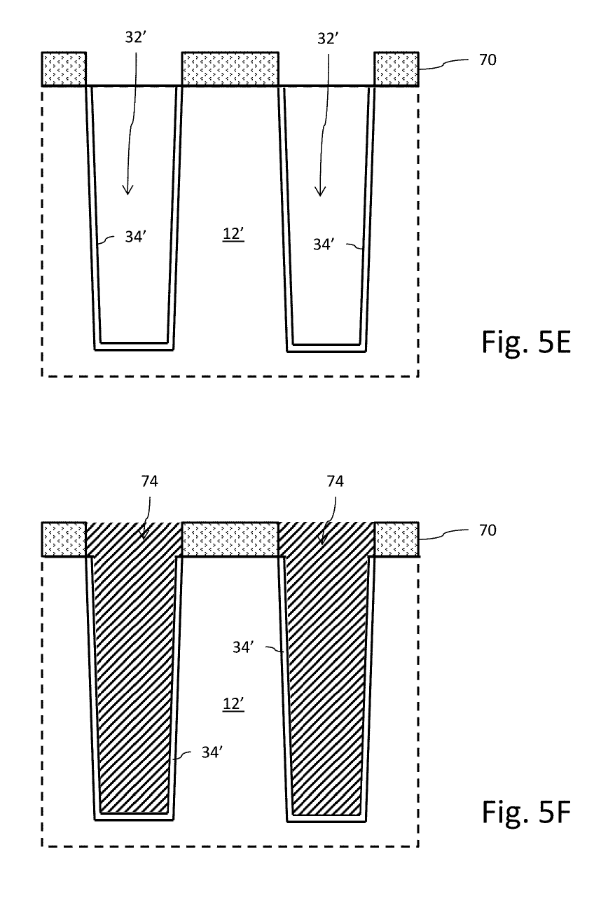

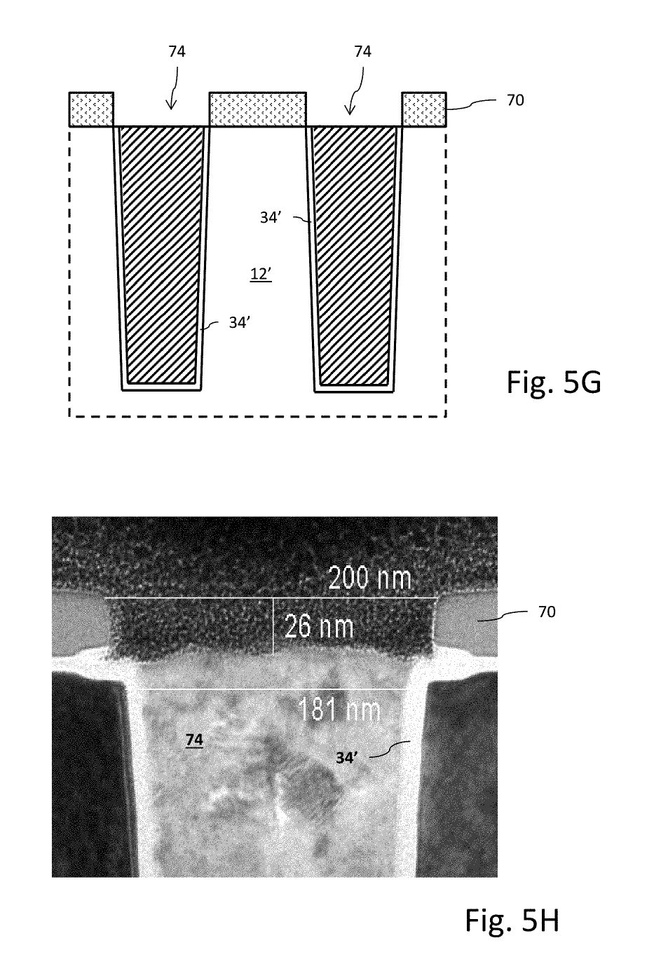

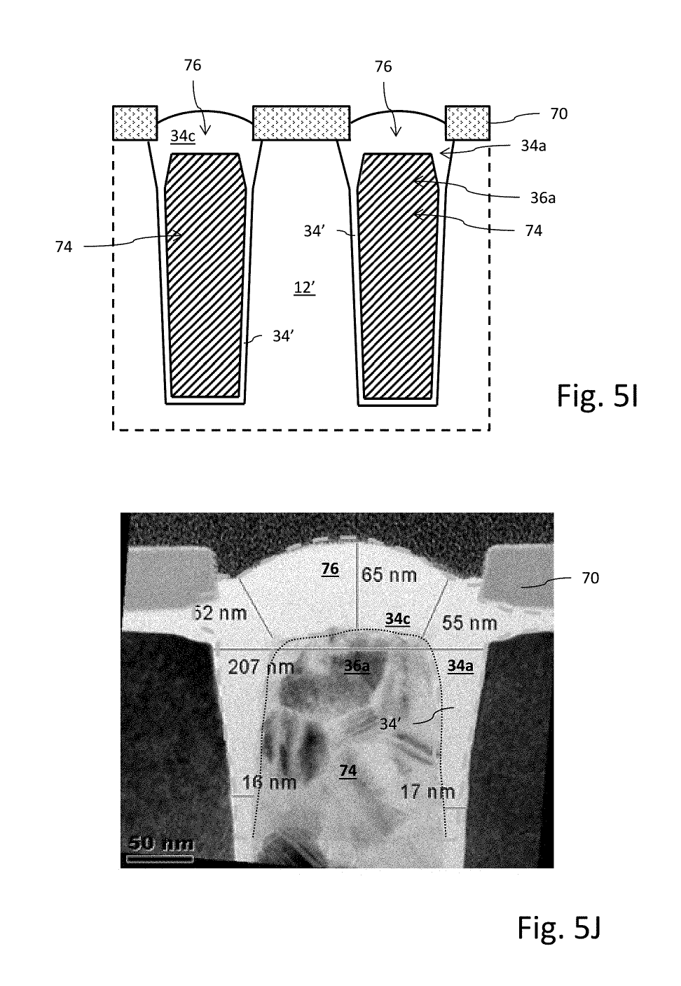

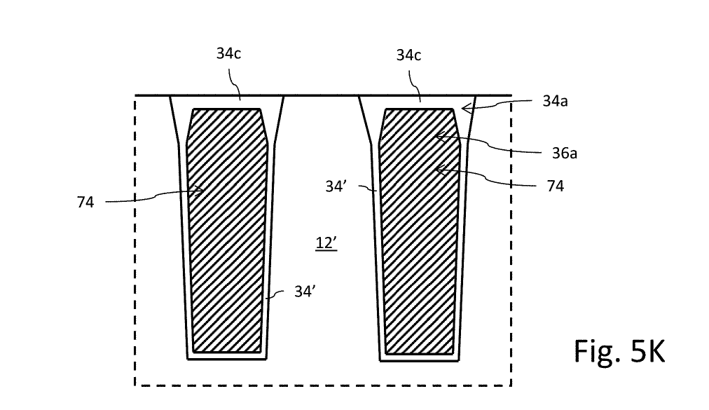

Reference is now made to FIGS. 5A-5K showing process steps for forming the insulated vertical gate electrode structure of FIG. 3.

FIG. 5A shows the substrate layer 12′. A hard mask 70 is deposited on the upper surface of substrate later 12′ as shown in FIG. 5B. The hard mask 70 is then patterned as shown in FIG. 5C to form mask openings 72 are locations where the insulated vertical gate electrode structure is to be formed. A trench etch is then performed through the mask openings 72 to open trenches 32′ in the substrate layer 12′ as shown in FIG. 5D. The trench etch may, for example, comprise wet etch (hot ammonia) or a dry plasma etch. A thermal oxidation is then performed to produce a thin conformal insulating oxide layer (liner) 34′ on the sidewalls and bottom of the trenches 32′ as shown in FIG. 5E. The trenches 32′ are then filled with a deposit of polysilicon material 74 (for example, using chemical vapor deposition) and a chemical mechanical polishing (CMP) is performed to produce the structures as shown in FIG. 5F. An etch-back process is then performed to remove a portion of the deposited polysilicon material 74, with the deposited polysilicon material 74 recessed to about the same level as the upper surface of the layer 12′ as shown in FIG. 5G. The etch used for the etch back may, for example, comprise an SF₆ plasma dry silicon etch. FIG. 5H shows a photomicrograph of the cross-section at this point in the process. A thermal oxidation is then performed which converts a portion of the deposited polysilicon material 74 and a portion of the layer 12′ at and near the mask openings 72 to an insulating oxide material 76. This produces the structure shown in FIG. 5I forming the upper conductive part 36a and the upper insulating part 34a adjacent to the upper conductive part 36a, and also the cap 34c. FIG. 5J shows a photomicrograph of the cross-section at this point in the process. The thermal oxidation process is, for example, a high temperature thermal silicon oxidation process comprising dry or steam oxidation at a temperature of 950° C. (+/−100° C.). To control the slope of the sidewalls of the upper conductive part 36a, an oxide recess (using an HF wet chemistry etch) followed by another high temperature thermal silicon oxidation may be performed so as to produce a steeper slope. The oxide recess and thermal oxidation may be repeated as needed to achieve the desired slope. The hard mask 70 is then removed and a chemical mechanical polishing (CMP) is performed to produce a planar upper surface as shown in FIG. 5K.

The foregoing description has provided by way of exemplary and non-limiting examples a full and informative description of the exemplary embodiment of this invention. However, various modifications and adaptations may become apparent to those skilled in the relevant arts in view of the foregoing description, when read in conjunction with the accompanying drawings and the appended claims. However, all such and similar modifications of the teachings of this invention will still fall within the scope of this invention as defined in the appended claims.

1. An integrated circuit, comprising:
a semiconductor substrate doped with a first conductivity type;
a top region in said semiconductor substrate, said top region doped with the first conductivity type but having a higher doping concentration than the semiconductor substrate;
wherein the semiconductor substrate includes a trench surrounding said top region and a portion of said semiconductor substrate; and
a vertical insulated gate structure in said trench, said vertical insulated gate structure comprising:
an insulating liner on sidewalls and a bottom of said trench; and
an electrode including an upper conductive part and a lower conductive part, wherein a width of the upper conductive part, said width extending parallel to an upper surface of the semiconductor substrate, increases as depth from the upper surface of the semiconductor substrate increases.

2. The integrated circuit of claim 1, wherein said insulating liner further comprises an insulating cap portion on top of the upper conductive part of the electrode.

3. The integrated circuit of claim 2, wherein a thickness of said insulating cap portion, said thickness extending perpendicular to the upper surface of the semiconductor substrate, is 90-110 nm.

4. The integrated circuit of claim 1, wherein said insulating liner comprises:
an upper insulating part adjacent the upper conductive part of the electrode; and
a lower insulating part adjacent the lower conductive part of the electrode;
wherein the upper insulating part has a thickness, said thickness extending parallel to the upper surface of semiconductor substrate, that decreases as depth from the upper surface of the semiconductor substrate increases.

5. The integrated circuit of claim 4, wherein a thickness of the lower insulating part is substantially constant.

6. The integrated circuit of claim 5, wherein said thickness of the lower insulating part is 10-14 nm.

7. The integrated circuit of claim 4, wherein said thickness of the upper insulating part adjacent the upper conductive part of the electrode decreases from a maximum thickness of 40-60 nm to a minimum thickness of 10-14 nm as depth from the upper surface of the semiconductor substrate increases.

8. The integrated circuit of claim 1, wherein the portion of said semiconductor substrate, the top region and the electrode form for a channel region, drain region and gate region of a vertical transistor.

9. The integrated circuit of claim 8, wherein said vertical transistor is a transfer gate transistor of a cell for an image sensor.

10. The integrated circuit of claim 8, wherein a charge collection region of said semiconductor substrate forms a source region of said vertical transistor.

11. The integrated circuit of claim 10, wherein said vertical transistor is a transfer gate transistor of a cell for an image sensor and said charge collection region collects photogenerated charges within said cell.

12. The integrated circuit of claim 1, wherein said upper conductive part in cross-section perpendicular to the upper surface has a trapezoidal shape.

13. The integrated circuit of claim 1, wherein said upper conductive part in cross-section perpendicular to the upper surface has a dome shape.

14. The integrated circuit of claim 1, wherein a width of the lower conductive part, said width extending parallel to the upper surface of the semiconductor substrate, decreases as depth from the upper surface of the semiconductor substrate increases.

15-21. (canceled)

22. An integrated circuit, comprising:
a semiconductor substrate; and
a vertical insulated gate structure extending into said semiconductor substrate from an upper surface of the semiconductor substrate, said vertical insulated gate structure comprising:
a trench;
an insulating liner on sidewalls and a bottom of said trench; and
an electrode within said trench and isolated from the semiconductor substrate by the insulating liner, wherein the electrode includes an upper conductive part and a lower conductive part, wherein a width of the upper conductive part, said width extending parallel to the upper surface of the semiconductor substrate, increases as depth from the upper surface of the semiconductor substrate increases.

23. The integrated circuit of claim 22, further including a doped region within the semiconductor substrate and located adjacent the trench, said doped region having a higher doping concentration than the semiconductor substrate.

24. The integrated circuit of claim 22, further including an insulating cap on top of the upper conductive part of the electrode.

25. The integrated circuit of claim 24, wherein the insulating cap has a thickness, said thickness extending perpendicular to the upper surface of the semiconductor substrate, of 90-110 nm.

26. The integrated circuit of claim 22, wherein said insulating liner comprises:
an upper insulating part adjacent the upper conductive part of the electrode; and
a lower insulating part adjacent the lower conductive part of the electrode;
said upper insulating part having a thickness, said thickness extending parallel to the upper surface of semiconductor substrate, that decreases as depth from the upper surface of the semiconductor substrate increases; and
said lower insulating part having a thickness, said thickness extending parallel to the upper surface of semiconductor substrate, that is constant.

27. The integrated circuit of claim 26, wherein said constant thickness of the lower insulating part is 10-14 nm.

28. The integrated circuit of claim 26, wherein said decreasing thickness of the upper insulating part ranges from a maximum thickness of 40-60 nm to a minimum thickness of 10-14 nm as depth from the upper surface of the semiconductor substrate increases.

29. The integrated circuit of claim 22, wherein said upper conductive part in cross-section perpendicular to the upper surface has a trapezoidal shape.

30. The integrated circuit of claim 22, wherein said upper conductive part in cross-section perpendicular to the upper surface has a dome shape.

31. The integrated circuit of claim 22, wherein a width of the lower conductive part, said width extending parallel to the upper surface of the semiconductor substrate, decreases as depth from the upper surface of the semiconductor substrate increases.
